(19) United States
(12) Patent Application Publication
(10) Pub. No.: US 2004/0150108 A1
(43) Pub. Date: Aug. 5, 2004

(54) Low resistance barrier for a microelectronic component and method for fabricating the same

(76) Inventors: Axel Buerke, Dresden (DE); Ulrike Bewersdorff-Sarlette, Radebeul (DE)

Correspondence Address: SHAW PITTMAN LLP, 1650 TYSONS BOULEVARD, MCLEAN, VA, 22102, US

(21) Appl. No.: 10/724,136

(22) Filed: Dec. 1, 2003

(30) Foreign Application Priority Data
Nov. 29, 2002 (DE) 102 55 835.3

(51) Int. Cl. H01L 23/48

(52) U.S. Cl. 257/751

(57) ABSTRACT

A microelectronic component is described having a barrier layer formed from WNₓ and a method is described for fabricating such a microelectronic component. The stoichiometry of the barrier formed from WNₓ is chosen such that 0.5>x>0.3 holds true. The barrier has a very high thermostability and also a low electrical resistance and is therefore suitable in particular for use in a gate stack.

### BACKGROUND

1. Field of the Invention

The invention relates to a microelectronic component having at least one barrier layer formed from WNₓ and to a method for fabricating such a microelectronic component.

2. Background Information

As power and storage capacity of microchips have been continually increasing, the integration density of the electronic components, such as transistors or capacitors, has continually increased. In this regard, Moore's law, which describes a doubling of the integration density in a period of 18 months, has held true for more than 30 years. Looking ahead, it will be endeavored to further increase the performance of microchips in the context of Moore's law and even under that for special components such as, for example, video chips, and so electronic components must be miniaturized further.

A higher degree of integration is essentially achieved by further reducing the size of the electronic components. This leads at the same time to an increase in the operating speed of the microchip. Therefore, the realization of submicron structures is at the present time one of the most important tasks for the further development of microelectronics. This gives rise to more stringent requirements made of the entire technology for fabricating microelectronic components. The individual technological steps must in part be utilized right up to their fundamental limits and new methods must be developed and introduced into industrial production.

In memory chips, transistors are used for driving the capacitors, the gate electrode of said transistors usually being constructed from a layer made of polysilicon. However, it has been shown that with this material, narrow limits are imposed on reducing the electrode height and increasing the operating speed of the circuit. Reduction of the electrode height is desirable for process technological reasons, since the planarity of the integrated circuit can be improved in this way, as a result of which, in turn, the quality of the photolithographic processes used is improved. However, reducing the electrode height reduces the cross-sectional area thereof, which in turn leads to an increase in the resistance of the electrode.

The operating speed of the circuit also depends, however, on the conductivity of the gate electrode or of the gate tracks. In order to increase this, it is desirable to use materials with low resistivity. Consequently, alternative materials allowing a further reduction of the resistivity of the layer from which the gate electrode is patterned have been sought.

By applying an additional layer of a metal silicide or, in the next development stage, a metal with a low electrical resistance on the electrode layer, it has been possible to increase the conductivity of the electrode. A gate electrode then comprises, for example, a layer made of polysilicon on which is deposited a layer made of tungsten silicide, and finally a cap nitride layer. The reaction between polysilicon and tungsten silicide proceeds to such a controlled extent that there is no need for a barrier layer between the polysilicon layer and the tungsten silicide layer in order to maintain a structure once it has been produced or the electrical properties of said structure over relatively long periods of time. However, if, in order to further reduce the electrical resistance of the electrode, the tungsten silicide layer is replaced by a layer made of pure tungsten, it is necessary to arrange a barrier layer between the layer made of polysilicon and the tungsten layer since otherwise the metals of the two layers react to form tungsten silicide, which has a lower electrical conductivity in comparison with pure tungsten metal. The advantages obtained by using tungsten would therefore be lost again.

In another possible integration scheme, the tungsten layer is applied directly on the gate oxide. Tungsten metal has a significantly higher electrical conductivity than tungsten silicide. In this case, too, it is necessary to apply a barrier layer between gate oxide and tungsten electrode since otherwise the tungsten metal is converted into tungsten oxide at the interface.

Further arrangements in which a barrier layer is necessary are for example contact areas between an electrically active region, for example a doped region in a silicon substrate for the definition of an electrode, and a contact plug to an interconnect. Equally, trenches which are introduced into a dielectric for the fabrication of interconnects must first of all be lined with a barrier layer in order to prevent the metal, for example copper or tungsten, from later diffusing from the interconnect into underlying layers, such as regions of the silicon substrate, or into the dielectric.

A barrier layer has to satisfy various requirements in order to be able to be used in a microchip. The barrier layer must adhere on the material on which it is deposited. Furthermore, it must also provide a sufficient adhesion for those materials that are subsequently to be deposited on the barrier layer. The barrier layer must be stable with respect to the production processes occurring during the fabrication of a microchip and must not deteriorate in terms of its functionality, e.g. with regard to adhesion, stability and electrical contact resistance, for example at temperatures as are used during the fabrication of microchips. In the case of an arrangement as barrier between two electrically conductive components, for example between a polysilicon layer and a tungsten layer as described above, the barrier layer must not adversely influence the high electrical conductivity desired. Therefore, the barrier layer should have an electrical resistance that is as low as possible. Finally, the barrier layer must be able to be fabricated without any defects and retain its barrier function during operation of the microchip over relatively long periods of time, through to several years.

Tungsten nitride (WNₓ) has properties by virtue of which it appears to be suitable for use as a barrier layer. It can be deposited by means of physical vapor deposition (PVD) or by means of chemical vapor deposition (CVD) in thin layers which exhibit a high stability even in the case of small layer thicknesses of less than 30 nm. Tungsten nitride can be deposited with different stoichiometry as an amorphous or polycrystalline layer depending on the quantities of nitrogen precursor compound and tungsten precursor compound supplied. Precursor compounds are compounds which contain elements of the compound to be produced and which react together with further precursor compounds to form the desired compound.

B.-S. Suh, H.-K. Cho, Y.-J. Lee, W.-J. Lee and C.-O. Park (J. Appl.-Phys., 89, 4128-4133 (2001)) report on the crystallization of amorphous WNₓ layers. The authors produced WNₓ layers by sputtering of a 99.95% W target in an Ar/N₂ atmosphere. The composition of the layer was varied by setting the proportion of nitrogen N₂/Ar+N₂ to 5%, 10%, 15%, 20%, 25%, 30% and 40% with a constant pressure. The WNₓ layer was in each case deposited on a silicon wafer to a layer thickness of 100 nm. The composition of the WNₓ layers was examined in each case by means of Auger electron spectroscopy (AES). The WNₓ layers with a proportion of nitrogen of 16%, 21%, 26% and 32% exhibited an amorphous structure, while the WNₓ layers with a nitrogen content of 40%, 42% and 44% had a polycrystalline structure. The substrates were subjected to heat treatment in an atmosphere comprising 10% H₂/Ar for one hour and the structure of the heat-treated layer was subsequently examined again by means of x-ray diffraction. The polycrystalline W₂N layers exhibited no phase change up to a temperature of 800° C., while the amorphous films began to crystallize at temperatures of between 450 and 600° C. and were converted into a two-phase mixture of W and W₂N at temperatures of between 600 and 700° C. Above 800° C., all the layers liberated nitrogen, so that a layer made of tungsten was obtained. In order to test the barrier properties, a copper layer with a thickness of 130 nm was in each case deposited on the WNₓ layer and the substrate was subsequently subjected to heat treatment as described above in an atmosphere comprising 10% H₂/Ar for one hour. The amorphous WNₓ layers maintained their barrier properties up to temperatures of 800° C., while local defects occurred in the polycrystalline W₂N layers at 800° C. The authors explain the better barrier properties of the amorphous WNₓ layers even after crystallization of the layer by citing the denser structure thereof. The crystallized layers obtained from amorphous WNₓ layers contain large primary crystals made of W₂N, the interspaces between the crystals being filled with a mixture of W and W₂N microcrystals. Therefore, diffusion paths on which copper atoms can enter into the silicon layer arranged opposite the WNₓ barrier layer can largely be suppressed.

U.S. Pat. No. 6,340,629 describes a method for fabricating gate electrodes for semiconductor components. To that end, firstly a gate oxide layer is produced on a silicon substrate, a layer made of doped silicon being deposited on said gate oxide layer. A diffusion barrier made of tungsten nitride, preferably having a nitrogen content of 5-20 atomic %, is deposited on the silicon layer. By means of heat treatment, the tungsten nitride layer is converted into a double layer comprising a tungsten silicon nitride layer (WSiN) and a tungsten layer. The tungsten silicon layer formed adjoining the silicon layer acts as a diffusion barrier which prevents a reaction between the tungsten layer and the silicon layer. The tungsten layer, arranged right at the top, acts as a seed layer for the deposition of a further tungsten layer. This tungsten layer is produced by chemical vapor deposition after the heat treatment. The tungsten layer has a thickness of about 500-1000 Å. Afterward, the gate electrode is patterned in a customary manner by first of all applying an insulating layer made of SiO₂ or Si₃N₄, for example, from which a mask for the etching of the electrode structure is produced.

### SUMMARY

As components realized in a microchip are miniaturized further, there is an increase in requirements for the corresponding materials used and also the methods for depositing and patterning them. Particularly, reliable functionality must be ensured, even in the case of electronic components having feature sizes of less than 90 nm. Embodiments are described in which a microelectronic component has at least one barrier layer formed from WNₓ.

In the barrier layer, the “x” is selected to be between 0.3 and 0.5.

A method is described for fabricating a microelectronic component. At least one barrier layer is formed from WNₓ. An area is provided from a first layer of a structural element of the microelectronic component onto which the barrier layer is deposited, and a second layer is deposited on the barrier layer. The barrier layer is deposited on the area from a nitrogen precursor compound and a tungsten precursor compound, the deposited quantity of the tungsten precursor compound and the deposited quantity of the nitrogen precursor compound selected such that x assumes a value of between 0.3 and 0.5.

The invention is explained in more detail below with reference to diagrammatic drawings and on the basis of preferred exemplary embodiments.

### BRIEF DESCRIPTION OF THE DRAWINGS

The invention is explained in more detail below on the basis of examples and also with reference to the accompanying figures, in which:

FIG. 1A-1C illustrates a section through different embodiments of a microelectronic component in accordance with aspects of the present invention;

FIG. 2 illustrates an electron microscope recording of a break through a layer stack comprising W/WNₓ/poly-Si;

FIG. 3 illustrates the electrical conductivity of a W/WNₓ-poly-Si layer stack as a function of x.

### DETAILED DESCRIPTION

In investigations of the properties of WNₓ layers, it was found that WNₓ barriers having a stoichiometry within a range of 0.3<x<0.5 have a very high thermal stability, on the one hand, and, on the other hand, the electrical resistance of the WNₓ barrier is significantly lower than that of a layer made of WN or WN₂, for example. The thermal stability of the barrier was able to be demonstrated up to temperatures of 1080° C. By virtue of its high thermostability, the barrier retains its structure under the process conditions that are usually used for the fabrication of microchips, thereby ensuring a function of the microelectronic component in the completed microchip.

The barrier also exhibits a very good adhesion on materials as are used in the fabrication of microchips. Equally, materials of this type can also be deposited on the WNₓ barrier layer according to an embodiment of the present invention, with good adhesion of the layers on the barrier being achieved. Thus, the WNₓ barrier layer adheres very well on oxide layers, such as silicon dioxide, and can therefore be used, for example, as a barrier layer in the fabrication of interconnects and contact structures in order to suppress a diffusion of the metal, such as copper or tungsten, from the interconnect or the contact structure into underlying or surrounding layers.

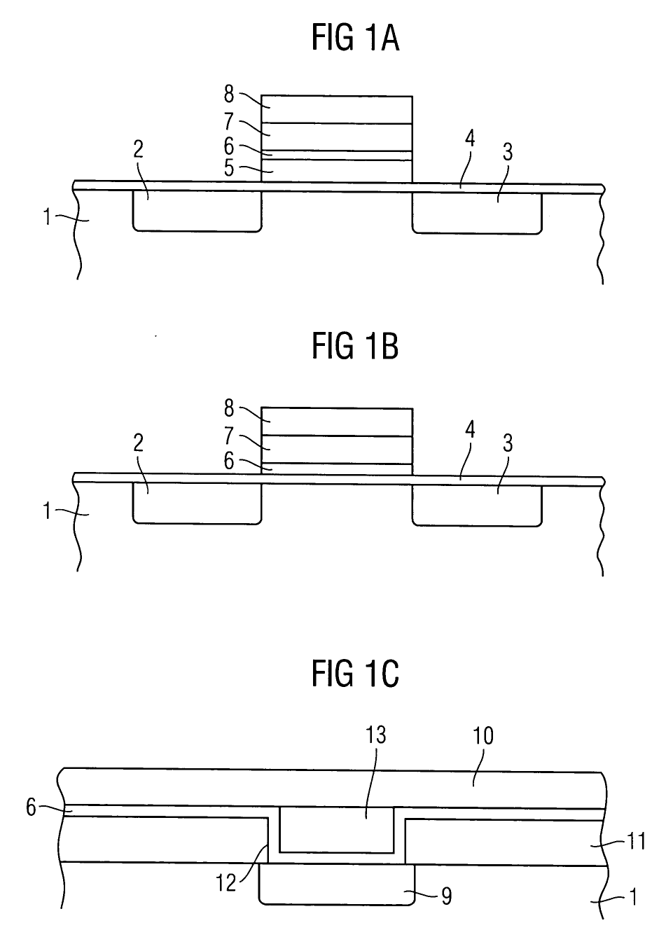

FIG. 1A diagrammatically shows a section through a field-effect transistor whose gate electrode comprises a barrier layer formed from WNₓ where x is chosen to be between 0.3 and 0.5. Doped regions are implanted as source 2 and drain 3 in a silicon substrate 1. The silicon substrate 1 is covered with an oxide layer 4, which also forms the gate dielectric. The oxide layer 4 is composed of silicon dioxide, for example. A layer 5 made of polysilicon, having a thickness of 20-200 nm, for example, is arranged on the oxide layer 4. A thin barrier 6 made of WNₓ, where 0.3<x<0.5 holds true, is deposited on the layer 5. The WNₓ barrier layer 6 has a thickness in the range of 1 to 50 nm, for example. The WNₓ barrier 6 may be produced from suitable tungsten and respectively nitrogen precursor compounds by means of a CVD method, for example. A layer 7 made of tungsten metal is arranged on the WNₓ barrier 6. The thickness of this layer may be chosen in the range of 20-100 nm, for example. The tungsten layer 7 may be applied by customary methods. A vapor phase deposition is suitable, by way of example, in which case WF₆, for example, is used as precursor compounds for tungsten, said WF₆ being reduced in an H₂ atmosphere. The layer stack constructed from the layers 5 and 7 and also the WNₓ barrier 6 forms the gate electrode of the transistor. The layer stack may also be terminated by a covering layer 8. A layer made of Si₃N₄ or SiO₂ is suitable, by way of example. The individual layers are fabricated and patterned according to known methods. In this case, the transistor may be constructed inherently in any desired manner, with the result that it is also possible to realize other configurations of the electrodes, for example.

The layer 5 made of polysilicon illustrated in FIG. 1A may also be dispensed with. An arrangement of this type is illustrated in FIG. 1B. Electrically active regions are once again defined as source 2 and drain 3 in a silicon substrate 1. On the undoped section of the silicon substrate 1 that is arranged between source 2 and drain 3, an oxide layer 4 is defined as a gate oxide, on which a WNₓ barrier 6 is arranged directly. The further construction corresponds to the illustration from FIG. 1A. A tungsten layer 7 is arranged on the WNₓ barrier 6, thereby obtaining a gate electrode. The upper termination of the gate electrode is once again formed by a covering layer 8, for example a nitride layer.

The WNₓ barrier layer contained in the microelectronic component according an aspect of the invention is generally suitable as a barrier between two electrically conductive layers. An exemplary arrangement of a contact is illustrated in FIG. 1C. A structural element 9, which is to be driven electrically via an interconnect 10, is arranged in a silicon substrate 1. For insulation purposes, a layer 11 made of a dielectric is applied on the silicon substrate 1, a contact opening 12 having been introduced into said layer by customary methods. The contact opening 12 and also the surface of the dielectric layer 11 are covered with a WNₓ barrier 6. In the contact opening 12, a contact plug 13 made of a conductive material, for example copper, is applied on the WNₓ barrier 6. The contact plug 13 leads to the interconnect 10, which is likewise composed of copper, by way of example. A good electrical contact between the structural element 9 and the contact plug 13 is ensured, on the one hand, by the WNₓ barrier 6. On the other hand, a diffusion of the electrically conductive material, for example copper, from the interconnect 10 or the contact plug 13 into the surrounding material of the dielectric layer 11 or the element 9 is effectively suppressed.

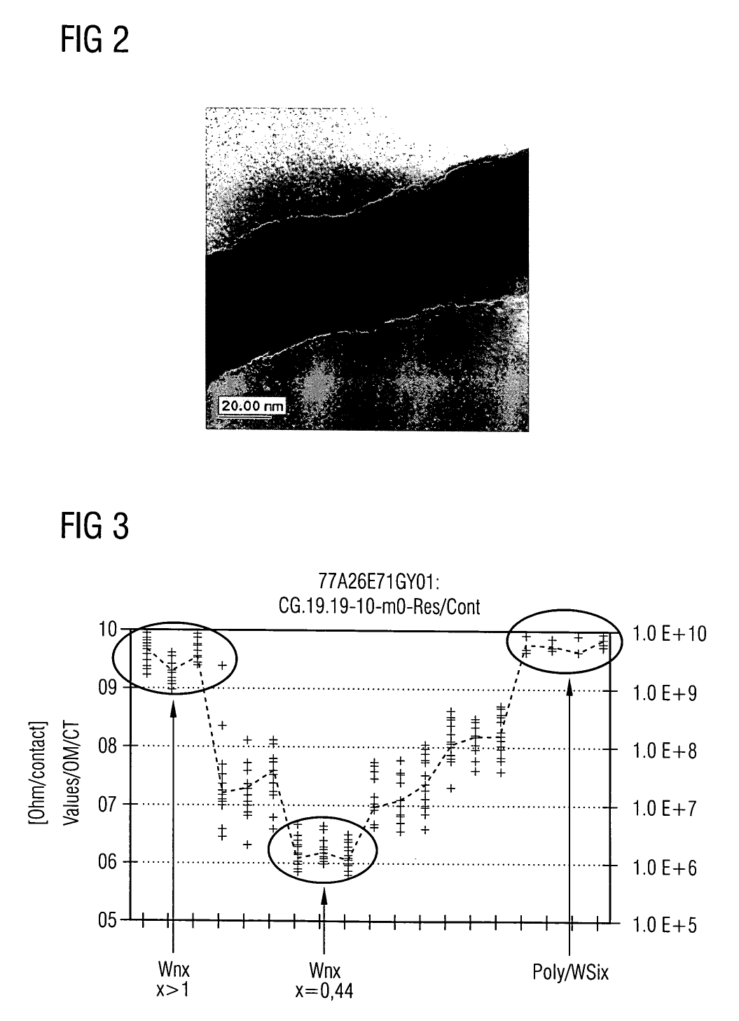

A layer stack as has been described diagrammatically in the various embodiments of the microelectronic component according to the invention with reference to FIG. 1 is represented as an electron microscope recording in FIG. 2. In this case, firstly a WNₓ barrier is deposited on a layer 5 made of polysilicon, a tungsten layer 7 again being deposited on said barrier. The layer stack shown was subjected to heat treatment at 950° C. for two minutes after the deposition. It can be seen that, despite the high temperature, the structure of the WNₓ barrier 6 is preserved and a clear separation of the regions of the silicon layer 5 and of the tungsten layer 7 is ensured.

The advantageous properties of the WNₓ barrier layer according to the invention are manifested particularly if the low electrical resistance of the barrier can be utilized. The WNₓ barrier layer can therefore be used particularly advantageously in microelectronic components in which a first layer made of a conductive material adjoins at least one side of the barrier layer formed from WNₓ. On the opposite side, by way of example, an oxide layer may adjoin the barrier layer formed from WNₓ, which may act as a gate dielectric. Oxidation of the conductive material of the first layer by oxygen atoms in-diffusing from the oxide layer can then be effectively suppressed. The electrical resistance of the electrode is not adversely influenced by the high electrical conductivity of the WNₓ barrier. The use of materials having a high electrical conductivity therefore makes it possible e.g. to produce electrodes having reduced dimensions, which, as a further advantage, also enable shorter switching times of the microelectronic components.

The barrier layer formed from WNₓ is furthermore suitable for the demarcation of two layers made of conductive materials. In the microelectronic component, in this case, a second layer made of a conductive material adjoins that side of the barrier layer formed from WNₓ which is opposite to the first layer made of a conductive material, with the result that a layer stack comprising two layers made of conductive materials and a barrier layer formed from WNₓ arranged between said layers is obtained. In this case, the conductive materials of the first layer and of the second layer may be identical or preferably different. Layer stacks of this type are found for example when connecting an electrically active region, such as the source or drain electrode of a transistor, to an interconnect. The element to be driven, in this case the transistor's electrode to be driven, forms, in the sense of the invention, for example the first layer and the material of the contact to the interconnect forms the second layer. The barrier layer formed from WNₓ is then arranged between the two layers, thereby effectively suppressing a diffusion of the metal atoms between contact and electrode.

However, the barrier layer formed from WNₓ may also be arranged within a structural element of the microelectronic component, for example as constituent parts of an electrode. Thus, the barrier layer formed from WNₓ may be a constituent part of a gate electrode of a transistor. In this case, the gate electrode comprises a plurality of layers made of different electrically conductive materials, individual layers of the electrode being separated by a barrier layer formed from WNₓ. In this case, the microelectronic component according to the invention comprises a layer stack constructed from at least the first layer made of a conductive material, the barrier layer formed from WNₓ, and the second layer made of a conductive material. The layer stack then forms e.g. the gate electrode of the transistor.

The WNₓ barrier layer provided in the microelectronic component according to the invention makes it possible to effectively suppress a diffusion of atoms from or into the first layer. It is therefore possible to use materials which have a very high electrical conductivity but react with materials from adjoining layers. In this case, owing to its high electrical conductivity, tungsten is particularly preferred as material for the first layer.

The second layer, which is arranged opposite to the first layer on or under the barrier layer formed from WNₓ, may inherently comprise any desired materials. Owing to its easy patternability or for reasons of better adhesion, it may be expedient for specific applications to fabricate the second layer from polysilicon. The barrier layer formed from WNₓ effectively prevents a reaction between silicon and for example tungsten from which the first layer is fabricated, so that, by way of example, an electrode having a high electrical conductivity may be obtained.

The properties of the barrier layer are determined by the stoichiometry of the WNₓ layer, which can be established by means of the fabrication conditions. Therefore, the invention also relates to a method for fabricating a microelectronic component having at least one barrier layer formed from WNₓ, an area of a first layer being provided, a barrier layer formed from WNₓ being deposited on the area from a nitrogen precursor compound and a tungsten precursor compound, the deposited quantity of the tungsten precursor compound and the deposited quantity of the nitrogen precursor compound being chosen such that x assumes a value of between 0.3 and 0.5, a second layer being deposited on the barrier layer formed from WNₓ, and the microelectronic component subsequently being completed in a customary manner.

What is significant to the method according to the invention is that the composition of the barrier layer formed from WNₓ is precisely controlled. The composition of the barrier layer formed from WNₓ can be determined by customary methods, for example Auger electron spectroscopy or Rutherford backscattering. In this way, the desired high electrical conductivity of the barrier layer can be established very precisely, the functionality and stability being ensured even during subsequent thermal treatments up to 1080° C.

As already described further above, the barrier layer formed from WNₓ can be used for various applications within a microelectronic component. The corresponding first layer or the area onto which the barrier layer formed from WNₓ is to be deposited is selected depending on the intended application. By way of example, the area may be provided from an oxide layer, in particular a gate oxide layer. However, the area may also be provided from a layer made of an electrically conductive material, for example a layer made of polysilicon.

The barrier layer formed from WNₓ can inherently be fabricated by customary methods. Thus, the barrier layer formed from WNₓ may be produced for example by means of a chemical vapor deposition (CVD). In this case, the chemical vapor deposition is carried out in a customary manner, using customary precursor compounds for tungsten and nitrogen. WF₆, for example, may be used as precursor compound for tungsten. NH₃ or N₂, for example, is suitable as precursor compound for nitrogen. In this case, the chemical vapor deposition may also be carried out sequentially. The barrier layer formed from WNₓ is in this case fabricated by means of an ALD method (ALD=Atomic Layer Deposition).

The barrier layer formed from WNₓ may also be produced by means of a physical vapor deposition (PVD). In this case, a tungsten target may be used for example as precursor compound for the tungsten, said tungsten target being sputtered in an N₂ atmosphere. Therefore, the customary conditions which the person skilled in the art can determine straightforwardly by means of corresponding preliminary experiments may likewise be selected for the physical vapor deposition.

As already described above, the barrier layer formed from WNₓ is distinguished in particular by its high electrical conductivity. It is therefore suitable in particular for use in electrical contacts. Therefore, in the method according to the invention, a second layer made of a conductive material is preferably deposited on the barrier layer formed from WNₓ.

All customary materials for use in microchips may inherently be used as the conductive material. Owing to its high electrical conductivity, tungsten is particularly preferably used as the conductive material of the second layer.

The barrier layer formed from WNₓ may inherently be deposited on any desired materials. By way of example, an oxide layer which is used to form a gate dielectric is suitable. However, for the fabrication of electrodes, it may also be advantageous if the area is provided from a first layer made of a conductive material. The electrode may then be formed as a layer stack.

In a preferred embodiment, the conductive material of the first layer is polysilicon which may also have a doping in order to increase the electrical conductivity.

### EXAMPLE

In order to show the low electrical contact resistance of the WNₓ barrier, identical layer stacks comprising a layer made of polysilicon on which is arranged a WNₓ barrier which is in turn covered by a layer made of pure tungsten metal were produced in each case. The nitrogen proportion of the WNₓ barrier was varied systematically and the electrical contact resistance of the layer stack was determined in each case. The results of these measurements are illustrated in table 1 and also in FIG. 3. In FIG. 3, the value for x is plotted on the abscissa and the electrical contact resistance of the contact is plotted logarithmically on the ordinate. The contact resistance for a layer stack comprising polysilicon and tungsten silicide is also specified for comparison purposes.

TABLE 1
Contact resistance of a layer stack poly-
Si/WNₓ/W with variation of x:

| x (WN)ₓ | Chain contact resistance (Ω/contact) |
|---|---|
| 0.4 | 1 × 10⁶ |
| 0.58 | 2 × 10⁷ |
| 0.66 | 2 × 10⁷ |
| 1.0 | 1 × 10⁸ |
| 1.2 | 5 × 10⁹ |
| poly-Si/Wsi | 9 × 10⁹ |

It can be seen that the layer stack investigated has a high resistance for values of x>1, said resistance decreasing greatly with decreasing values of x and reaching a minimum in the range of 0.5>x>0.3. As values of x decrease further, the thermal stability of the WNₓ barrier is no longer ensured. Finally, the value for a layer stack comprising polysilicon and tungsten silicide is specified as a reference. When using a WNₓ barrier with the stoichiometry described above, it is thus possible to minimize the electrical contact resistance of the layer stack whilst simultaneously ensuring a high thermal stability.

The foregoing disclosure of embodiments of the present invention has been presented for purposes of illustration and description. It is not intended to be exhaustive or to limit the invention to the precise forms disclosed. Many variations and modifications of the embodiments described herein will be obvious to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

What is claimed is:

1. A microelectronic component comprising at least one barrier layer formed from WNₓ, where x is selected as a value between 0.3 and 0.5.

2. The microelectronic component of claim 1, further comprising a first layer made of a conductive material adjoining at least one side of the barrier layer formed from WNₓ.

3. The microelectronic component of claim 2, further comprising a second layer made of a conductive material adjoining the side of the barrier layer formed from WNₓ, opposite to the first layer made of a conductive material,
wherein the first layer and of the second layer may be comprised of the same conductive material.

4. The microelectronic component of claim 3, further comprising a layer stack that is constructed from at least the first layer made of a conductive material,
the barrier layer formed from WNₓ and the second layer made of a conductive material forming a contact between an interconnect and a structural element of the microelectronic component.

5. The microelectronic component of claim 3, further comprising a layer stack that is constructed from at least the first layer made of a conductive material,
the barrier layer formed from WNₓ and the second layer made of a conductive material forming a gate electrode of a transistor.

6. The microelectronic component of claim 3, wherein at least one of the first layer and the second layer is constructed from tungsten.

7. The microelectronic component of claim 3, wherein at least one of the first layer and the second layer being constructed from polysilicon.

8. A method for fabricating a microelectronic component comprising:
forming at least one barrier layer from WNₓ;
providing an area from a first layer of a structural element of the microelectronic component for depositing the barrier layer; and
depositing a second layer on the barrier layer;
wherein the barrier layer is deposited on the area from a nitrogen precursor compound and a tungsten precursor compound, the deposited quantity of the tungsten precursor compound and the deposited quantity of the nitrogen precursor compound selected such that x assumes a value of between 0.3 and 0.5.

9. The method of claim 8, wherein the barrier layer formed from WNₓ is deposited by means of a chemical vapor deposition.

10. The method of claim 8, wherein the barrier layer formed from WNₓ is deposited by means of a physical vapor deposition.

11. The method of claim 8, wherein the first layer is constructed from a conductive material.

12. The method of claim 8, wherein the second layer deposited on the barrier layer formed from WNₓ is constructed from an electrically conductive material.

13. The method of claim 8, wherein the first and second layer is constructed from tungsten.

14. The method of claim 8, wherein at least one of the first and second layer is constructed of polysilicon.

15. The method of claim 14, wherein the polysilicon is doped.
